(19) United States
(12) Patent Application Publication
(10) Pub. No.: US 2006/0076695 A1
(43) Pub. Date: Apr. 13, 2006

(54) Semiconductor package with flash-absorbing mechanism and fabrication method thereof

(75) Inventors: Wen-Chen Hsieh, Taichung Hsien (TW); Hsiu-Fang Chien, Taichung Hsien (TW); Chien-Te Chen, Taichung Hsien (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/234,652

(22) Filed: Sep. 23, 2005

(30) Foreign Application Priority Data
Sep. 29, 2004 (TW) 093129362

(51) Int. Cl. H01L 23/28

(52) U.S. Cl. 257/787

(57) ABSTRACT

A semiconductor package with flash-absorbing mechanism and a fabrication method thereof are proposed, wherein a flash-absorbing structure is formed on a gold-plated copper layer of a substrate, and adhesion between the flash-absorbing structure and a molding material is larger than that between the molding material and a mold, such that flashes of the molding material are not adhered to the mold after completing a molding process unlike the conventional technology, thereby ensuring quality of the fabricated semiconductor package.

### FIELD OF THE INVENTION

The present invention relates to semiconductor packages and fabrication methods thereof, and more particularly, to a semiconductor package with flash-absorbing mechanism and a method for fabricating the semiconductor package.

### BACKGROUND OF THE INVENTION

Ball Grid Array (BGA) packaging technology, which is an advanced well-known technology in the relevant art, is performed in a manner as to mount a semiconductor chip on a front side of a substrate and implant a plurality of array-arranged solder balls on a back side of the substrate. The array-arranged solder balls are customarily referred to as a ball grid array for bonding and electrically connecting the entire package unit to an external device such as a printed circuit board.

One type of the BGA packaging technology is named Flip-Chip Ball Grid Array (FCBGA) packaging technology, by which the semiconductor chip is mounted on the front side of the substrate in a face-down manner via a plurality of solder bumps and is electrically connected to the external device via the ball grid array formed on the back side of the substrate. Such obtained FCBGA package is advantageous without using relatively space-occupied bonding wires for electrically connecting the semiconductor chip to the substrate, thereby significantly reducing the overall size of the package. Due to this superior characteristic of the FCBGA package, Flip-Chip Chip Scale Packaging (FCCSP) technology is further developed to be capable of making the size of the package unit very close to the size of an incorporated semiconductor chip.

Relevant patents to the FCBGA packaging technology include U.S. Pat. No. 6,038,136 entitled “Chip Package with Molded Underfill”; U.S. Pat. No. 6,319,450 entitled “Encapsulated Circuit Using Vented Mold”; and U.S. Pat. No. 6,324,069 entitled “Chip Package with Molded Underfill”.

FIGS. 1A to 1C are cross-sectional schematic diagrams showing a molding process of a chip packaging method disclosed in U.S. Pat. No. 6,038,136. As shown, a set of molds 30, 34 are used in the molding process for packaging a semiconductor chip 12 on a substrate 14. The set of molds 30, 34 are formed with a ball receiving cavity 36, a flash runner 38, a mold cavity 40, a flash receiving cavity 42, a gate 44, and an air vent 46. The substrate 14 is formed with a vent hole 26 and a plurality of solder balls 24. Detailed description of the molding process is disclosed in U.S. Pat. No. 6,038,136 and not to be further repeated herein.

A characteristic feature of U.S. Pat. No. 6,038,136 is provision of the vent hole 26 underneath the semiconductor chip 12 such that air in the molds 30, 34 is vented through the vent hole 26 during the molding process when a molding material 16 is injected, thereby preventing formation of voids under the semiconductor chip 12 and adverse effect on the molding quality.

However, the above patented technology is not suitable for a FCBGA package because the distribution of mold flow is unable to allow air under a flip chip to be completely vented. Further, forming the vent hole in the substrate affects a circuit layout of the substrate and easily makes external moisture enter the package structure.

FIGS. 2A to 2E provide a solution to the foregoing problem, which employs a method of filling the molding material from one end and enhancing air venting at the other end to achieve optimal molding quality. Referring to FIGS. 2A and 2B, a substrate 110 and a set of semiconductor chips 120 are firstly prepared.

The substrate 110 has a front side 110a and a back side 110b, wherein the front side 110a is formed with a solder mask (S/M) 111 thereon. The front side 110a of the substrate 110 is further defined with a molding area 112, wherein a plurality of chip attach areas 113 are defined in the molding area 112 (bond pads and conductive traces in the chip attach areas 113 are not shown). A recessed gold-plated copper layer 115 is formed on the front side 110a of the substrate 110 at a position adjacent to the molding area 112 and is not covered by the solder mask 111, wherein a space on the recessed gold-plated copper layer 115 serves as an air vent.

A plurality of solder bumps 121 are formed on an active surface 120a of each of the chips 120 by a bumping process so as to subsequently mount the chips 120 on the substrate 110 via a flip-chip technique.

As shown in FIG. 2C, a chip-bonding process is performed to mount each of the chips 120 via the flip-chip technique on a corresponding one of the chip attach areas 113 in the molding area 112 on the front side 110a of the substrate 110, wherein the chips 120 are bonded and electrically connected to the substrate 110 by the solder bumps 121.

As shown in FIG. 2D, a molding process is performed to place the substrate 110 together with the chips 120 mounted thereon in a mold 130, wherein an air vent 132 is formed at a side of the molding area 112 adjacent to the gold-plated copper layer 115, and a gate 131 is formed at an opposite side of the molding area 112, such that a molding material is injected into the mold 130 through the gate 131. During the molding process, the molding material gradually and completely fills an internal cavity of the mold 130 by venting air in the mold 130 through the air vent 132, so as to form an encapsulant 140 on the molding area 112.

As shown in FIG. 2E, if the molding material flashes to the gold-plated copper layer 115 through the air vent 132, since adhesion between the molding material and the mold 130 is larger than that between the molding material and the gold-plated copper layer 115, flashes 141 of the molding material are adhered to the mold 130 after removing the mold 130 and completing the molding process. However, when such mold 130 is used again for a next molding process, the flashes 141 adhered to the mold 130 may easily block the air vent 132 and result in a fabricated package with degraded quality.

Therefore, the problem to be solved here is to develop a semiconductor package and a fabrication method thereof, which can prevent flashes of a molding material from being adhered to a mold and ensure quality of the fabricated semiconductor package.

### SUMMARY OF THE INVENTION

In light of the foregoing drawback in the conventional technology, a primary objective of the present invention is to provide a semiconductor package with flash-absorbing mechanism and a fabrication method thereof, which can prevent flashes of a molding material from being adhered to a mold and ensure quality of the fabricated semiconductor package.

In accordance with the above and other objectives, the present invention proposes a fabrication method of a semiconductor package, comprising the steps of: preparing a substrate having a front side and a back side, wherein a molding area is defined on the front side of the substrate and at least one chip attach area is defined in the molding area, and wherein a gold-plated copper layer is formed on the front side of the substrate at a position adjacent to the molding area and a flash-absorbing structure is formed on the gold-plated copper layer; mounting at least one semiconductor chip on the chip attach area of the front side of the substrate; and performing a molding process to place the substrate together with the chip thereon in a mold, wherein an air vent is formed at a side of the molding area adjacent to the gold-plated copper layer, and a gate is formed at another side of the molding area, such that a molding material is injected into the mold through the gate and fills an internal cavity of the mold by venting air in the mold through the air vent so as to form an encapsulant on the molding area of the front side of the substrate to encapsulate the chip; wherein adhesion between a material of the flash-absorbing structure and the molding material is larger than that between the molding material and the mold, such that when the molding material flashes on the gold-plated copper layer through the air vent, flashes of the molding material are adhered to the flash-absorbing structure on the gold-plated copper layer.

A semiconductor package fabricated by the above method in the present invention comprises: a substrate having a front side and a back side, wherein a molding area is defined on the front side of the substrate and at least one chip attach area is defined in the molding area, and wherein a gold-plated copper layer is formed on the front side of the substrate at a position adjacent to the molding area and a flash-absorbing structure is formed on the gold-plated copper layer; at least one semiconductor chip mounted on the chip attach area of the front side of the substrate; and an encapsulant formed on the molding area of the front side of the substrate to encapsulate the chip.

Therefore, in the semiconductor package and the fabrication method thereof according to the present invention, the flash-absorbing structure is formed on the gold-plated copper layer, wherein adhesion between a material of the flash-absorbing structure and a molding material for forming the encapsulant is larger than that between the molding material and a mold used in a molding process, such that flashes of the molding material are not adhered to the mold after completing the molding process, thereby ensuring quality of the fabricated semiconductor package.

### BRIEF DESCRIPTION OF THE DRAWINGS

The invention can be more fully understood by reading the following detailed description of the preferred embodiments, with reference made to the accompanying drawings, wherein:

FIGS. 1A to 1C (PRIOR ART) are cross-sectional schematic diagrams showing a molding process of a chip packaging method as disclosed in U.S. Pat. No. 6,038,136;

FIG. 2A (PRIOR ART) is a cross-sectional view showing components employed in a conventional FCBGA packaging technology;

FIG. 2B (PRIOR ART) is a top view of a substrate used in the conventional FCBGA packaging technology;

FIG. 2C (PRIOR ART) is a cross-sectional view showing a chip-bonding process of the conventional FCBGA packaging technology;

FIG. 2D (PRIOR ART) is a cross-sectional view showing a molding process of the conventional FCBGA packaging technology;

FIG. 2E (PRIOR ART) is a cross-sectional view showing a deficient outcome resulted from the molding process of the conventional FCBGA packaging technology;

FIG. 3A is a cross-sectional view showing components employed in a fabrication method of a semiconductor package according to the present invention;

FIG. 3B is a top view of a substrate used in the fabrication method according to the present invention;

FIG. 3C is a cross-sectional view showing a chip-bonding process of the fabrication method according to the present invention;

FIG. 3D is a cross-sectional view showing a molding process of the fabrication method according to the present invention;

FIG. 3E is a cross-sectional view showing a satisfactory outcome resulted from the molding process of the fabrication method according to the present invention;

FIGS. 4A and 4B are cross-sectional schematic diagrams showing another example of a flash-absorbing structure employed in the fabrication method according to the present invention; and

FIG. 5 is a top view showing a further example of the flash-absorbing structure employed in the fabrication method according to the present invention.

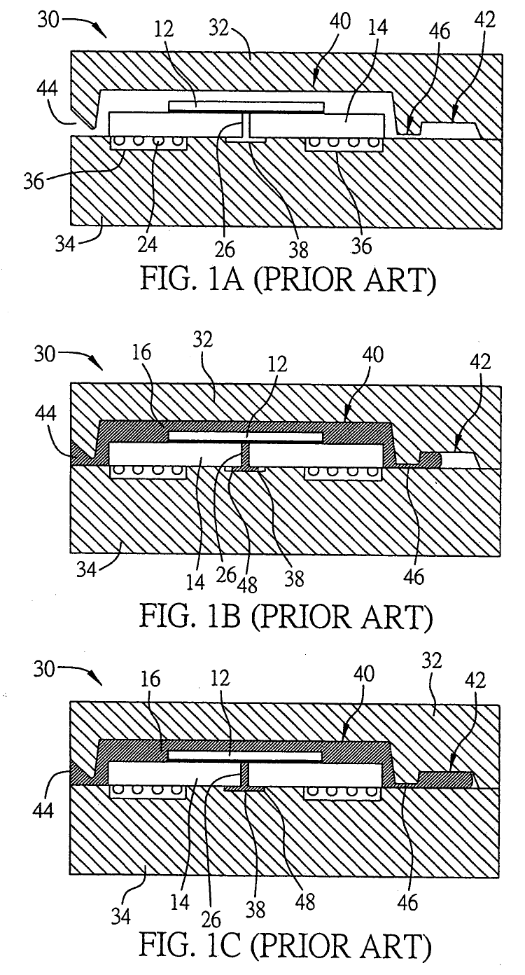

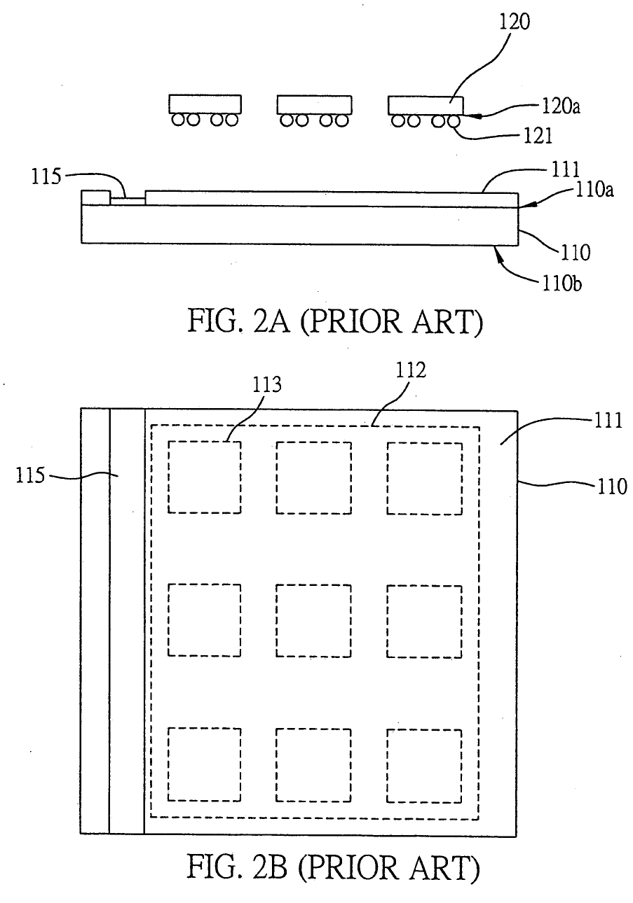

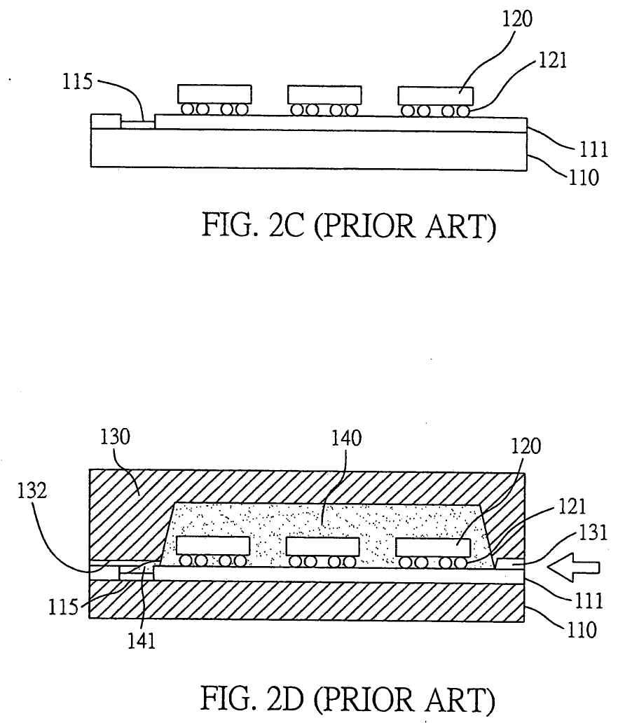

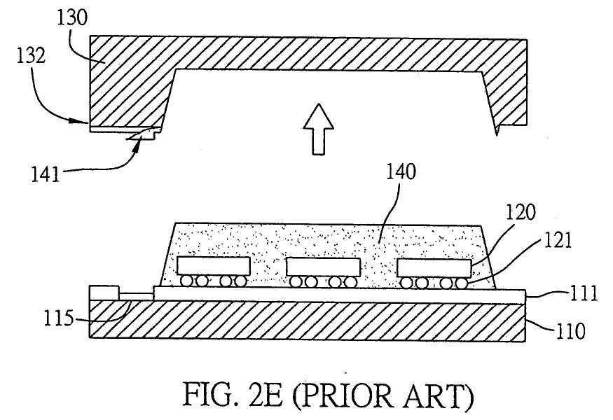

### DETAILED DESCRIPTION OF THE PREFERRED EMBODIMENTS

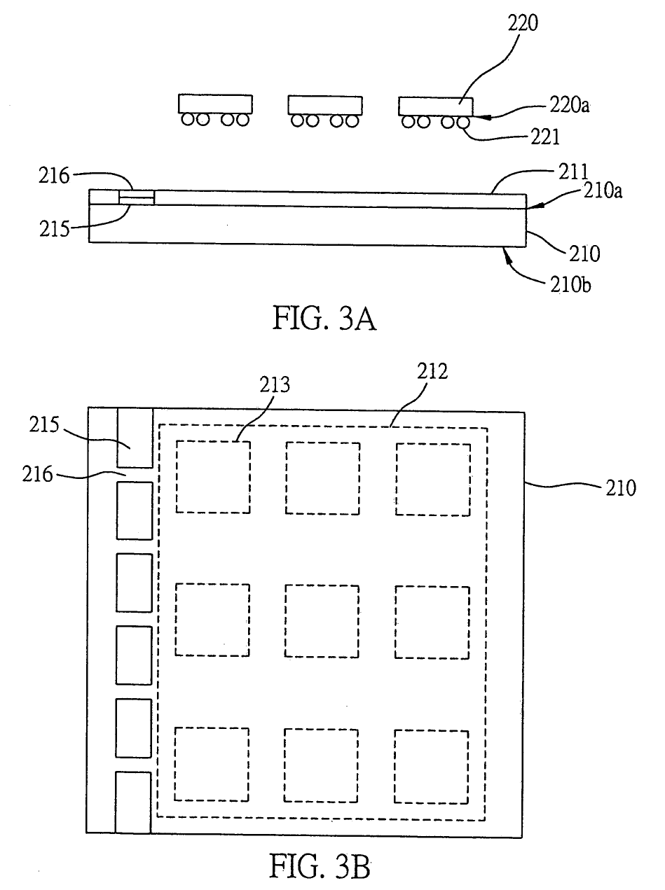

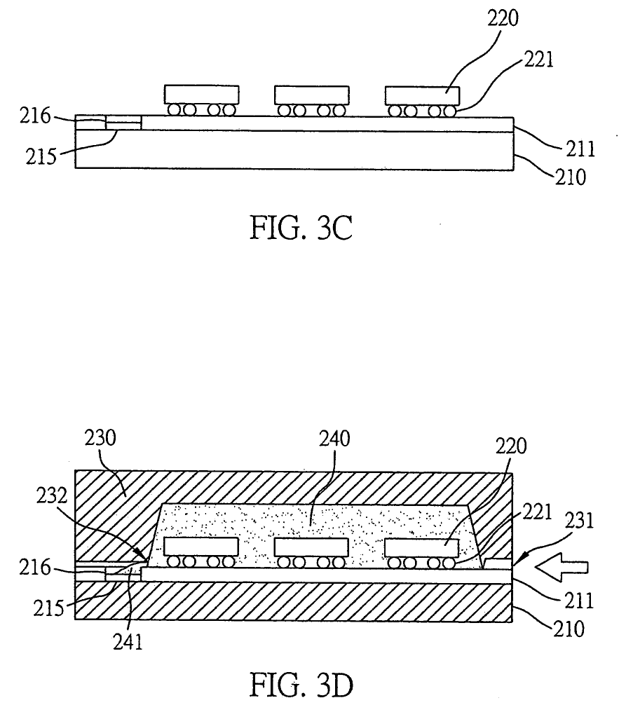

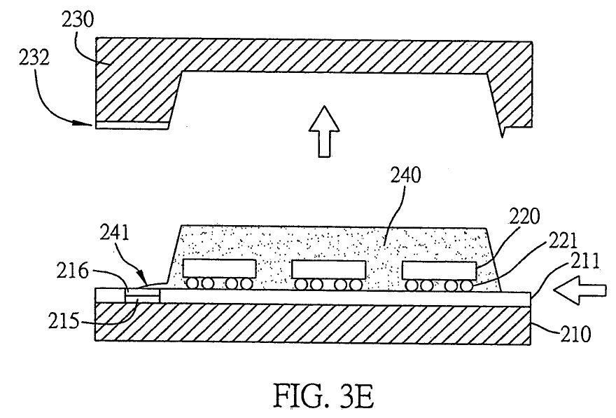

Preferred embodiments of a semiconductor package with flash-absorbing mechanism and a fabrication method thereof proposed in the present invention are described as follows with reference to FIGS. 3 to 5.

It should be noted that the accompanying drawings are simplified schematic diagrams only showing relevant components to the present invention to illustrate the basic concept of the present invention, wherein the number and size of the components are not made according to practical implementation. The configuration and layout of the semiconductor package should be more complex in practical implementation.

FIG. 3A to 3E show steps of a fabrication method of a semiconductor package according to the present invention.

Referring to FIGS. 3A and 3B, a substrate 210 and a set of semiconductor chips 220 are firstly prepared. It should be understood that the number of chips is flexibly adjusted according to the size of the substrate.

The substrate 210 can be a flat substrate made of BT (bismaleimide triazine), which has a front side 210a and a back side 210b. Each of the front and back sides 210a, 210b of the substrate 210 is formed with conductive traces. A solder mask 211 is applied on the front side 210a of the substrate 210, with electrical contacts on the front side 210a being exposed from the solder mask 211. The front side 210a of the substrate 210 is further defined with a molding area 212, wherein a plurality of chip attach areas 213 are defined in the molding area 212 (bond pads and conductive traces in the chip attach areas 213 are not shown). A recessed gold-plated copper layer 215 is formed on the front side 210a of the substrate 210 at a position adjacent to the molding area 212 and is not covered by the solder mask 211, such that a space on the recessed gold-plated copper layer 215 serves as an air vent. A flash-absorbing structure 216 is formed on the gold-plated copper layer 215, wherein adhesion between the flash-absorbing structure 216 and a molding material is larger than that between the molding material and a mold 230 used in a subsequent molding process (FIG. 3D).

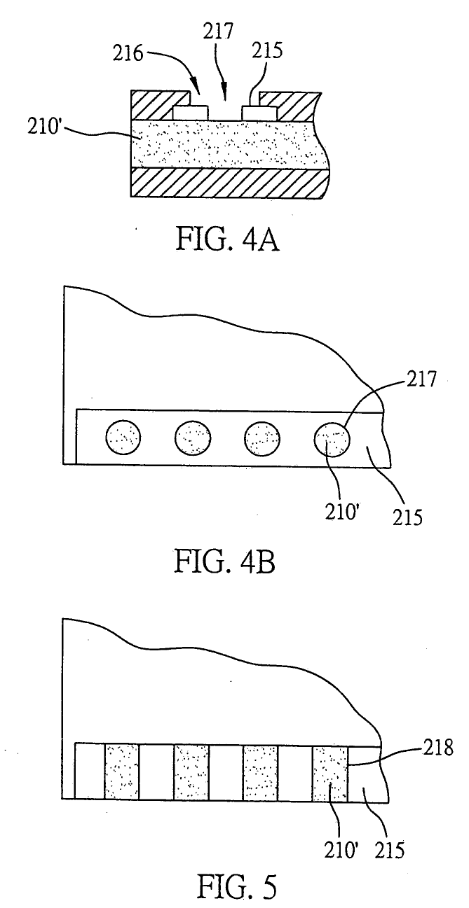

Various preferred embodiments of the foregoing flash-absorbing structure 216 are provided in the present invention. In one embodiment shown in FIGS. 3A to 3E, the flash-absorbing structure 216 is formed by directly applying a material of the solder mask 211 on the gold-plated copper layer 215. Generally, the flash-absorbing structure 216 can be made of any other materials having adhesion with the molding material larger than the adhesion between the molding material and the mold 230. In another embodiment shown in FIGS. 4A to 4B, an array of round windows 217 are formed in the gold-plated copper layer 215 to expose predetermined portions of a core layer 210′ of the substrate 210, and the exposed portions of the core layer 210′ serve as the flash-absorbing structure 216 to provide an enhanced ability of flash absorption. In a further embodiment shown in FIG. 5, an array of grooves 218 are formed in the gold-plated copper layer 215 to expose predetermined portions of the core layer 210′ of the substrate 210, and the exposed portions of the core layer 210′ serve as the flash-absorbing structure 216 to provide an enhanced ability of flash absorption.

A plurality of solder bumps 221 are formed on an active surface 220a of each of the chips 220 by a bumping process so as to subsequently mount the chips 220 on the substrate 210 via a flip-chip technique. Since the bumping process is a well-known technique in the art, it is not to be further detailed herein.

As shown in FIG. 3C, a chip-bonding process is performed to mount each of the chips 220 via the flip-chip technique on a corresponding one of the chip attach areas 213 in the molding area 212 on the front side 210a of the substrate 210, wherein the chips 220 are bonded and electrically connected to the substrate 210 by the solder bumps 221. Since the chip-bonding process is a well-known technique in the art, it is not to be further detailed herein.

As shown in FIG. 3D, the molding process is performed to place the substrate 210 together with the chips 220 mounted thereon in the mold 230, wherein an air vent 232 is formed at a side of the molding area 212 adjacent to the gold-plated copper layer 215, and a gate 231 is formed at an opposite side of the molding area 212, such that the molding material can be injected into the mold 230 via the gate 231. During the molding process, the molding material gradually and completely fills an internal cavity of the mold 230 by venting air in the mold 230 through the air vent 232, so as to form an encapsulant 240 on the molding area 212 of the substrate 210 to encapsulate the chips 220.

As shown in FIG. 3E, if the molding material flashes on the gold-plated copper layer 215 through the air vent 232, flashes 241 of the molding material are adhered to the flash-absorbing structure 216 on the gold-plated copper layer 215 and a bottom portion of the mold 230. Since the adhesion between the molding material and the flash-absorbing structure 216 is larger than that between the molding material and the mold 230, after removing the mold 230 and completing the molding process, the flashes 241 remain on the flash-absorbing structure 216 on the gold-plated copper layer 215 but are not adhered to the mold 230 unlike the conventional technology.

After completing the foregoing molding process, subsequent processes such as a ball-implanting process are performed, which are well-known techniques in the art and not to be further described herein.

A semiconductor package is thus fabricated by the above method shown in FIGS. 3A to 3E, comprising: a substrate 210 having a front side 210a and a back side 210b, wherein a molding area 212 is defined on the front side 210a and at least one chip attach area 213 is defined in the molding area 212, and wherein a gold-plated copper layer 215 is formed on the front side 210a at a position adjacent to the molding area 212 and a flash-absorbing structure 216 is formed on the gold-plated copper layer 215; at least one semiconductor chip 220 mounted on the chip attach area 213 of the substrate 210; and an encapsulant 240 formed on the molding area 212 of the substrate 210 to encapsulate the chip 220; wherein adhesion between a material of the flash-absorbing structure 216 and a molding material for forming the encapsulant 240 is larger than that between the molding material and a mold 230.

Therefore, in the semiconductor package and the fabrication method thereof according to the present invention, the flash-absorbing structure is formed on the gold-plated copper layer of the substrate, wherein adhesion between the flash-absorbing structure and the molding material is larger than that between the molding material and the mold, such that flashes of the molding material are not adhered to the mold after completing the molding process unlike the conventional technology, thereby ensuring quality of the fabricated semiconductor package.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A fabrication method of a semiconductor package, comprising the steps of:
preparing a substrate having a front side and a back side, wherein a molding area is defined on the front side of the substrate and at least one chip attach area is defined in the molding area, and wherein a gold-plated copper layer is formed on the front side of the substrate at a position adjacent to the molding area and a flash-absorbing structure is formed on the gold-plated copper layer;
mounting at least one semiconductor chip on the chip attach area of the front side of the substrate; and
performing a molding process to place the substrate together with the chip thereon in a mold, wherein an air vent is formed at a side of the molding area adjacent to the gold-plated copper layer, and a gate is formed at another side of the molding area, such that a molding material is injected into the mold through the gate and fills an internal cavity of the mold by venting air in the mold through the air vent so as to form an encapsulant on the molding area of the front side of the substrate to encapsulate the chip;
wherein adhesion between a material of the flash-absorbing structure and the molding material is larger than that between the molding material and the mold, such that when the molding material flashes on the gold-plated copper layer through the air vent, flashes of the molding material are adhered to the flash-absorbing structure on the gold-plated copper layer.

2. The fabrication method of claim 1, wherein the substrate further comprises a solder mask applied on the front side thereof, with the gold-plated copper layer being exposed from the solder mask.

3. The fabrication method of claim 1, wherein the substrate is made of bismaleimide triazine (BT).

4. The fabrication method of claim 2, wherein the material of the flash-absorbing structure is same as that of the solder mask.

5. The fabrication method of claim 1, wherein the flash-absorbing structure comprises predetermined portions of a core layer of the substrate, which are exposed via an array of round windows formed in the gold-plated copper layer.

6. The fabrication method of claim 1, wherein the flash-absorbing structure comprises predetermined portions of a core layer of the substrate, which are exposed via an array of grooves formed in the gold-plated copper layer.

7. A semiconductor package comprising:
a substrate having a front side and a back side, wherein a molding area is defined on the front side of the substrate and at least one chip attach area is defined in the molding area, and wherein a gold-plated copper layer is formed on the front side of the substrate at a position adjacent to the molding area and a flash-absorbing structure is formed on the gold-plated copper layer;
at least one semiconductor chip mounted on the chip attach area of the front side of the substrate; and
an encapsulant formed on the molding area of the front side of the substrate, for encapsulating the chip;
wherein adhesion between a material of the flash-absorbing structure and a molding material for the encapsulant is larger than that between the molding material and a mold.

8. The semiconductor package of claim 7, wherein the substrate further comprises a solder mask applied on the front side thereof, with the gold-plated copper layer being exposed from the solder mask.

9. The semiconductor package of claim 7, wherein the substrate is made of bismaleimide triazine (BT).

10. The semiconductor package of claim 8, wherein the material of the flash-absorbing structure is same as that of the solder mask.

11. The semiconductor package of claim 7, wherein the flash-absorbing structure comprises predetermined portions of a core layer of the substrate, which are exposed via an array of round windows formed in the gold-plated copper layer.

12. The semiconductor package of claim 7, wherein the flash-absorbing structure comprises predetermined portions of a core layer of the substrate, which are exposed via an array of grooves formed in the gold-plated copper layer.

13. A substrate for a semiconductor package, comprising a front side and a back side, wherein a molding area is defined on the front side of the substrate and at least one chip attach area is defined in the molding area, and wherein a gold-plated copper layer is formed on the front side of the substrate at a position adjacent to the molding area and a flash-absorbing structure is formed on the gold-plated copper layer, with adhesion between a material of the flash-absorbing structure and a molding material for the semiconductor package being larger than that between the molding material and a mold.

14. The substrate of claim 13, further comprising a solder mask applied on the front side of the substrate, with the gold-plated copper layer being exposed from the solder mask.

15. The substrate of claim 13, which is made of bismaleimide triazine (BT).

16. The substrate of claim 14, wherein the material of the flash-absorbing structure is same as that of the solder mask.

17. The substrate of claim 13, wherein the flash-absorbing structure comprises predetermined portions of a core layer of the substrate, which are exposed via an array of round windows formed in the gold-plated copper layer.

18. The substrate of claim 13, wherein the flash-absorbing structure comprises predetermined portions of a core layer of the substrate, which are exposed via an array of grooves formed in the gold-plated copper layer.
